(19) United States
(12) Patent Application Publication
(10) Pub. No.: US 2008/0068801 A1
(43) Pub. Date: Mar. 20, 2008

(54) High-Power Ultracapacitor Energy Storage Cell Pack and Coupling Method

(75) Inventor: Michael D. Wilk, Temecula, CA (US)

Correspondence Address: PROCOPIO, CORY, HARGREAVES & SAVITCH LLP, 530 B STREET, SUITE 2100, SAN DIEGO, CA, 92101, US

(73) Assignee: ISE CORPORATION, Poway, CA (US)

(21) Appl. No.: 11/946,143

(22) Filed: Nov. 28, 2007

Related U.S. Application Data
(63) Continuation-in-part of application No. 11/469,337, filed on Aug. 31, 2006.
(63) Continuation-in-part of application No. 11/460,738, filed on Jul. 28, 2006.
(63) Continuation of application No. 10/720,916, filed on Nov. 24, 2003, now Pat. No. 7,085,112.
(63) Continuation-in-part of application No. 09/972,085, filed on Oct. 4, 2001, now Pat. No. 6,714,391.

(51) Int. Cl. H05K 7/20; H05K 7/04

(52) U.S. Cl. 361/702; 361/811

(57) ABSTRACT

An ultracapacitor energy storage cell pack including an ultracapacitor assembly including a plurality of ultracapacitors, each ultracapacitor including opposite ends with connection terminals protruding therefrom for directly connecting the ultracapacitors end-to-end in series; and a plurality of interconnections for mechanically and electrically interconnecting the ultracapacitors end-to-end in series without the connection terminals from adjacent ultracapacitors contacting each other, preventing mechanical stress in the connection studs.

### CROSS-REFERENCE TO RELATED APPLICATIONS

This patent application is a continuation-in-part of U.S. patent application Ser. No. 11/469,337, filed Aug. 31, 2006, which is a continuation-in-part of U.S. patent application Ser. No. 11/460,738, filed Jul. 28, 2006, which is a continuation of U.S. patent application Ser. No. 10/720,916, filed Nov. 24, 2003, issued as U.S. Pat. No. 7,085,112 on Aug. 1, 2006, which is a continuation-in-part application of U.S. patent application Ser. No. 09/972,085, filed Oct. 4, 2001, issued as U.S. Pat. No. 6,714,391 on Mar. 30, 2004. These applications/patents are incorporated by reference herein as though set forth in full.

### FIELD OF THE INVENTION

The field of the invention relates to a high-voltage, high-power ultracapacitor energy storage pack composed of a large number of serially connected individual low-voltage ultracapacitor cells that store an electrical charge.

### BACKGROUND OF THE INVENTION

The connecting together of individual battery cells for high-voltage, high-energy applications is well known. However, the chemical reaction that occurs internal to a battery during charging and discharging typically limits deep-cycle battery life to hundreds of charge/discharge cycles. This characteristic means that the battery pack has to be replaced at a high cost one or more times during the life of a hybrid-electric or all-electric vehicle. Batteries are somewhat power-limited because the chemical reaction therein limits the rate at which batteries can accept energy during charging and supply energy during discharging. In a hybrid-electric vehicle application, battery power limitations restrict the drive system efficiency in capturing braking energy through regeneration and supplying power for acceleration.

Ultracapacitors are attractive because they can be connected together, similar to batteries, for high-voltage applications; have an extended life of hundreds of thousands of charge/discharge cycles; and can accept and supply much higher power than similar battery packs. Although ultracapacitor packs are typically more expensive than battery packs for the same applications and cannot store as much energy as battery packs, ultracapacitor packs are projected to last the life of the vehicle and offer better performance and fuel-efficient operation through braking regeneration energy capture and supplying of vehicle acceleration power.

Serially connected ultracapacitor cans (i.e., having a cylindrical form factor) are often connected end-to-end through connecting terminals on opposite ends of the ultracapacitor. A problem that has occurred in the field with ultracapacitor packs having multiple high power ultracapacitor cells is that inconsistent manufacturing tolerances in the connecting studs (e.g., stud angle and location) allow for rigidly connected cells to induce mechanical stress on the connecting studs, each other, and/or the structural support for the cell. If the connecting studs are stressed in a mobile application (e.g., in a transit bus) having a high vibration and shock environment, the ultracapacitor cans eventually crack and leak, leading to catastrophic failure of the ultracapacitor cells and ultimately loss of the entire ultracapacitor pack.

### SUMMARY OF THE INVENTION

The present invention involves an ultracapacitor pack incorporating a unique method of mechanically and electrically coupling the ultracapacitor cells end-to-end in series, using cell-to-cell interconnection devices, without mechanically stressing the connecting terminals of the ultracapacitor cells.

Another aspect of the invention involves an ultracapacitor energy storage cell pack including an ultracapacitor assembly having a plurality of ultracapacitors, each ultracapacitor including opposite ends with connection terminals protruding there from for directly connecting the ultracapacitors end-to-end in series; and a plurality of interconnections for mechanically and electrically interconnecting the ultracapacitors end-to-end in series without the connection terminals from adjacent ultracapacitors contacting each other, and preventing mechanical stress in the connection studs.

### BRIEF DESCRIPTION OF THE DRAWINGS

The accompanying drawings, which are incorporated in and form a part of this specification, illustrate embodiments of the invention and together with the description, serve to explain the principles of this invention.

FIG. 1 is an exploded perspective view drawing of an embodiment of a half module of an ultracapacitor energy storage cell pack.

FIG. 2 is a perspective view of an embodiment of an ultracapacitor energy storage cell pack.

FIG. 3 is a top plan view of an embodiment of a circuit board for the half module illustrated in FIG. 1 and ultracapacitor energy storage cell pack illustrated in FIG. 2.

FIG. 4 is an exploded perspective view of an alternative embodiment of an ultracapacitor energy storage cell pack.

FIG. 5 is an exploded perspective view of the ultracapacitors and support plates of the ultracapacitor energy storage cell pack of FIG. 4.

FIG. 6 is perspective detail view taken of detail 6 of the ultracapacitors, threaded interconnections between the ultracapacitors, and parallel drain resistors mounted with ring terminals of the ultracapacitor energy storage cell pack of FIG. 5.

FIG. 7 is a side-elevational view of an embodiment of a middle support plate of the ultracapacitor energy storage cell pack illustrated in FIG. 4, and the middle support plate is shown with cutouts for the ultracapacitors and the drain resistors.

FIG. 8 is a side-elevational view of an embodiment of an end support plate of the ultracapacitor energy storage cell pack illustrated in FIG. 4, and the end support plate is shown with cutouts for the mounting bolts and the support guide mounting rivets.

FIG. 9 is a block diagram of the ultracapacitor energy storage cell pack illustrated in FIG. 4.

FIG. 10 is a partial perspective view of another embodiment of an ultracapacitor energy storage cell pack.

FIG. 11 is a perspective view on an embodiment of a bus bar interconnection of the ultracapacitor energy storage cell pack of FIG. 10.

FIG. 12 is an exploded side elevational view of an embodiment of a fastening arrangement for one side of an ultracapacitor energy storage cell pack.

FIG. 13 is a side elevational view of the fastening arrangement of FIG. 12 shown in an assembled configuration.

FIG. 14 is a perspective view of a string of ultracapacitor cans of an ultracapacitor energy storage cell pack, and shows of an embodiment of an ultracapacitor cell to ultracapacitor cell interconnection device.

FIG. 15 is an enlarged perspective view of the ultracapacitor cell to ultracapacitor cell interconnection device of FIG. 14 taken from area 15 of FIG. 14.

FIG. 16 is an enlarged perspective view of the ultracapacitor cell to ultracapacitor cell interconnection device of FIGS. 14 and 15.

FIG. 17 is a perspective view of an embodiment of an ultracapacitor energy storage cell pack without a housing enclosure.

FIG. 18 is an enlarged perspective view of an end of the ultracapacitor energy storage cell pack of FIG. 17 taken from area 18 of FIG. 17.

FIG. 19 is a perspective view on an embodiment of a bus bar interconnection end plate of the ultracapacitor energy storage cell pack of FIGS. 17 and 18.

FIG. 20 is a perspective view on another embodiment of a bus bar interconnection end plate of the ultracapacitor energy storage cell pack of FIGS. 17 and 18.

### DETAILED DESCRIPTION OF PREFERRED EMBODIMENTS

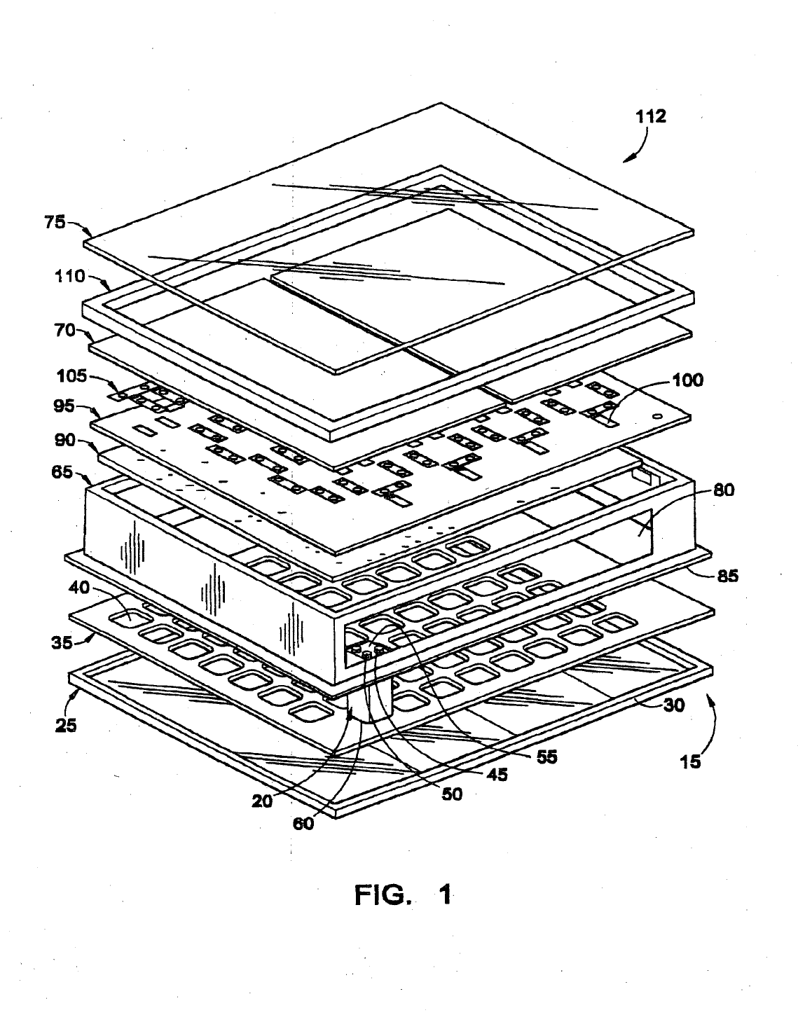

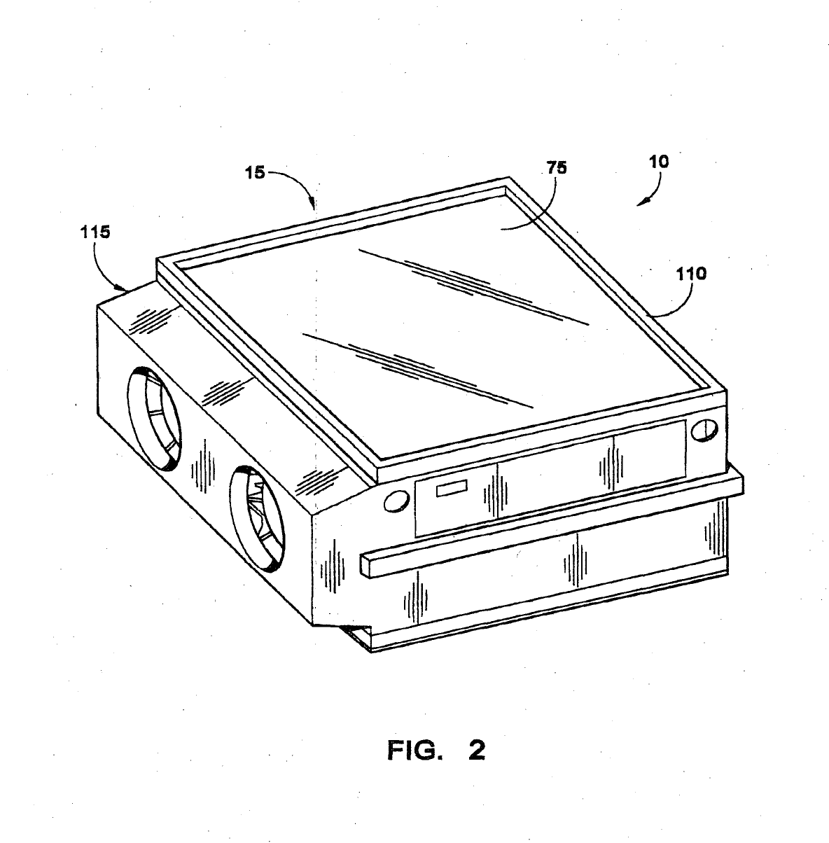

With reference to FIGS. 1 and 2, an embodiment of an ultracapacitor energy storage cell pack 10 will now be described. FIG. 1 illustrates an exploded view of an embodiment of a half module 15 of the ultracapacitor energy storage cell pack 10. FIG. 2 illustrates an embodiment of an assembled ultracapacitor energy storage cell pack module 10, which includes two half modules 15 fastened together. Although each half module 15 preferably includes eighty ultracapacitors 20, each half module may have other numbers of ultracapacitors 20. Further, the ultracapacitor pack 10 may have other numbers of modules 15 besides a pair (e.g., 1, 3, 4, etc.).

The ultracapacitor pack 10 is shown in exploded view in FIG. 1 to illustrate the different levels in the half module 15 that are added during assembly of the half module 15. Each of these levels will now be described in turn below followed by a description of the assembly process.

An aluminum base plate 25 forms a bottom or inner-most level of the half module 15. The base plate 25 includes a welded frame 30 around edges of the base plate 25.

A polycarbonate crate plate 35 is seated inside the frame 30 and includes cutouts or holes 40 with a shape that matches the cross-section of the ultracapacitors 20. The base plate 25 and crate cutouts 40 form an x, y, and z location and mounting support for the ultracapacitors 20. The cutouts 40 also prevent the ultracapacitors 20 from rotating during use, e.g., mobile vehicle use.

In the embodiment shown, the individual ultracapacitors 20 have a general square-can shape (i.e., rectangular parallelepiped). The cross-section of the ultracapacitors 20 is 2.38 in. by 2.38 in. and the length is about 6 in. On an upper-most or outer-most end of the ultracapacitor 20, two threaded lug terminals 45 and a dielectric paste fill port 50 protrude from an insulated cover 55 of the ultracapacitor 20. The cover 55 of the ultracapacitor may include a well encircled by a protruding rim. Shrink plastic that normally surrounds sides or exterior capacitor casing 60 of the ultracapacitor 20 is removed to better expose the exterior casing 60 to circulated cooling air. The shrink plastic may be left on the bottom of the ultracapacitor 20.

A box frame 65 ties together the base plate 25 and frame 30 with circuit boards 70, and a top polycarbonate cover 75. The box frame 65 has elongated lateral cutouts 80 on two opposing sides to provide for cross-flow air cooling. Bottom flanges 85 provide a mounting surface to tie two of these box frames 65, and, hence, two half modules 15, together to form the single ultracapacitor pack module 10 shown in FIG. 2. The box frame 65 includes a large upper rectangular opening and a large lower rectangular opening.

The next layer is a first ¼-in. foam rubber insulating and sealing sheet 90 that covers the ultracapacitors 20. The first sheet 90 has cutouts for the ultracapacitor terminals 45 and fill port 50 so that the sheet 90 can seal tightly against the cover 55 of the ultracapacitor 20.

A second ⅛-in. foam rubber insulating and sealing sheet 95 may be placed on top of the previous first sheet 90. The second sheet 95 includes rectangular cutouts or holes 100. The cutouts 100 receive copper bar electrical interconnections 105. The cutouts 100 in the sheet 95 simplify the assembly and proper placement of the copper bar electrical interconnections 105. The sheet 95 also seals the copper bar electrical interconnections 105. The copper bar electrical interconnections 105 include holes that the ultracapacitor terminals 45 protrude through.

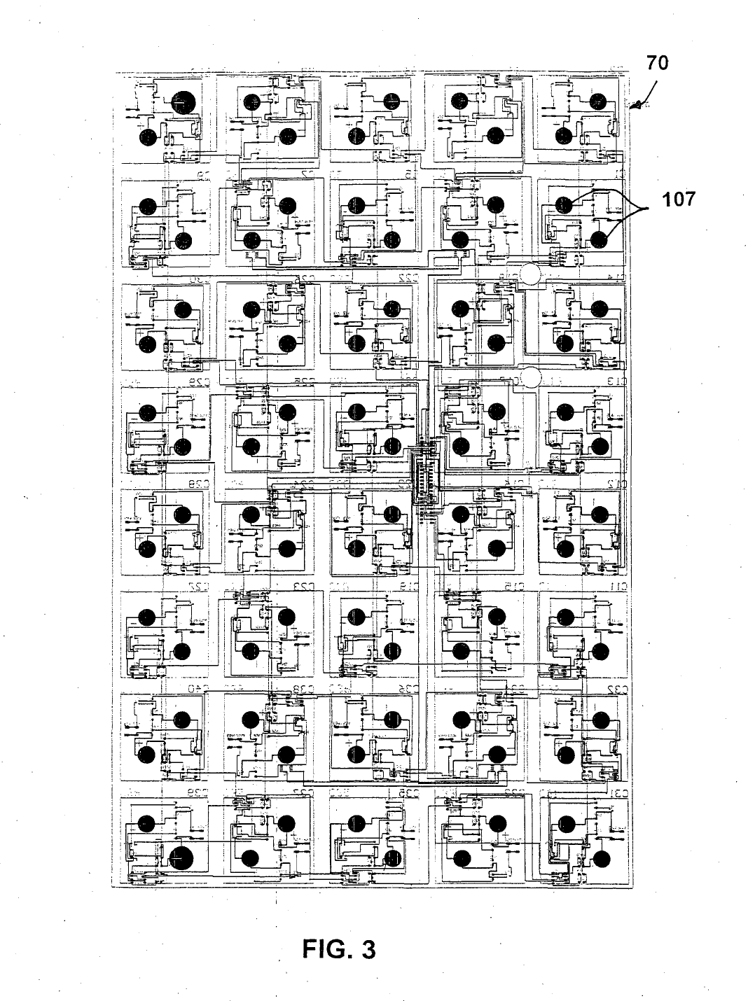

Two identical main circuit boards 70 (e.g., 40-ultracapacitor main circuit boards) may lay on top of the foam rubber sheets 90, 95. With reference additionally to FIG. 3, each main circuit board 70 may include holes 107 that the ultracapacitor terminals 45 protrude through. In the embodiment shown, each circuit board 70 may have mounting holes 107 for 40 (8 by 5) ultracapacitors less two corner positions required for frame structure mounting. Instead of two circuit boards 70, a single circuit board 70 may be used. Thus, as used herein, the word “circuit board” means one or more circuit boards. Fasteners such as lug nuts fasten the individual ultracapacitor terminals 45 and copper bars 105 to the circuit boards 70 and compress the foam rubber sheets 90, 95 in between the cover 55 of the ultracapacitor 20 and the circuit boards 70. Thus, the circuit board 70 forms the location and mechanical support as well as the electrical connections for the ultracapacitors 20. The foam sheets 90, 95 seal around the rim of the ultracapacitor terminals 45. A processor and display circuit board mounts on top of the main circuit board 70.

Although the ultracapacitor pack 10 and the half modules 15 are shown as being generally rectangular in shape, either or both may have shapes other than generally rectangular such as, but not by way of limitation, circular, oval, other curvilinear shapes, other rectilinear shapes, and other polygonal shapes.

A top aluminum frame 110 and the transparent polycarbonate cover 75 may attach to the frame structure to complete the half module 15. The transparent cover 75 allows observation of a light emitting diode (LED) failure detection display that indicates the active/inactive status of the ultracapacitors 20.

Together, the bottom base plate 25, crate plate 35, box frame 65, sealing sheets 90, 95, and circuit board(s) 70, and ultracapacitor terminal fasteners form an ultracapacitor mounting assembly 112 for the ultracapacitors 20. The ultracapacitor mounting assembly 112 provides a mounting surface for the copper bar interconnects 105, maintains the position and spacing of the ultracapacitors 20 in the X, Y, and Z directions, does not allow the ultracapacitors to rotate when connected, and the main circuit board(s) 70 provides a mounting platform for the cell equalization, failure detection, processor, and LED display systems. Attaching the ultracapacitors 20 to the mounting assembly 112 by the terminals 45 instead of the exterior ultracapacitor casing 60 allows the ultracapacitors 20 to be more effectively cooled because the majority of the surface area of the ultracapacitors 20 is in the cooling air stream supplied by the cross-flow air cooling assembly 115. Sealing along the cover 55 and around the terminals 45 protects the terminals 45 from water, dust, and other contaminants.

An exemplary method of assembling the ultracapacitor half module 15 will now be described. The ultracapacitors 20 are first placed onto the bottom base plate 25, with the bottoms of the ultracapacitors 20 extending through the square cutouts 40 of the crate plate 35. The box frame 65 is applied over the ultracapacitors 20, so that the ultracapacitors extend through the large lower and upper rectangular openings of the box frame 65. The ¼-in. foam rubber insulating and sealing sheet 90 is placed on top of the ultracapacitors 20, with the ultracapacitor terminals 45 and fill port 50 protruding through cutouts in the sheet 90. The ⅛-in. foam rubber insulating and sealing sheet 95 is placed on top of the previous sheet 90 and the copper bar electrical interconnections 105 are placed into the rectangular cutouts 100 of the sheet 95. The ultracapacitor terminals 45 also protrude through holes in the copper bar electrical interconnections 105. The main circuit boards 70 are layered on top of the foam rubber sheets 90, 95 so that the threaded ultracapacitor terminals 45 protrude through the corresponding holes in the circuit boards 70. Lug nuts are screwed onto the threaded terminals 45, compressing the foam rubber sheets 90, 95 in between the cover 55 of the ultracapacitor 20 and the circuit boards 70, and securing the ultracapacitors 20 and copper bars 105 in position. The processor and display circuit board is mounted on top of the main circuit board 70. The top aluminum frame 110 and the transparent polycarbonate cover 75 are placed over the circuit boards and attached to the frame structure to complete the half module 15. A pair of half modules 15 may be positioned back to back (i.e., facing opposite directions with the bottoms of the aluminum base plates 25 touching) and a cross-flow air cooling assembly 115 may be attached to the frame structure, adjacent the elongated lateral cutouts 80 on one side of the box frames 65. The half modules 15 may be bolted or otherwise fastened together at the respective bottom flanges 85 to complete the ultracapacitor pack module 10.

To determine if one or more ultracapacitors 20 in the pack 10 need to be replaced, a user observes the light emitting diode (LED) failure detection display through the transparent cover 75. The LED failure detection display includes an array of LEDs that correspond to the array of ultracapacitors 20, each LED indicating the status of a corresponding ultracapacitor 20. Each unlit LED indicates a corresponding failed LED. An ultracapacitor 20 in the pack 10 can quickly and easily be replaced by simply unfastening the frame and unbolting only the failed ultracapacitor 20 that had been previously identified by the LED display. The replacement ultracapacitor is put into position and the procedure reversed.

With reference to FIGS. 4-9, and initially, FIGS. 4 and 5, an ultracapacitor energy storage cell pack (hereinafter “ultracapacitor pack”) 200 constructed in accordance with another embodiment of the invention will now be described. The ultracapacitor pack 200 includes a ultracapacitor cell and wine rack style crate support assembly (hereinafter “ultracapacitor assembly”) 210, an ultracapacitor pack box enclosure (hereinafter “box enclosure”) 220, a metal lid 230, an air filter bracket 240 (w/air filter), cooling fans 250, fan finger guards 260, high-power precharge resistor 270, Programmable Logic Controller module (hereinafter “PLC”) 280, high power relays (kilovac contactors) 290, electrical connectors 300, 310, 320 and other discrete components mounted within the box enclosure 220.

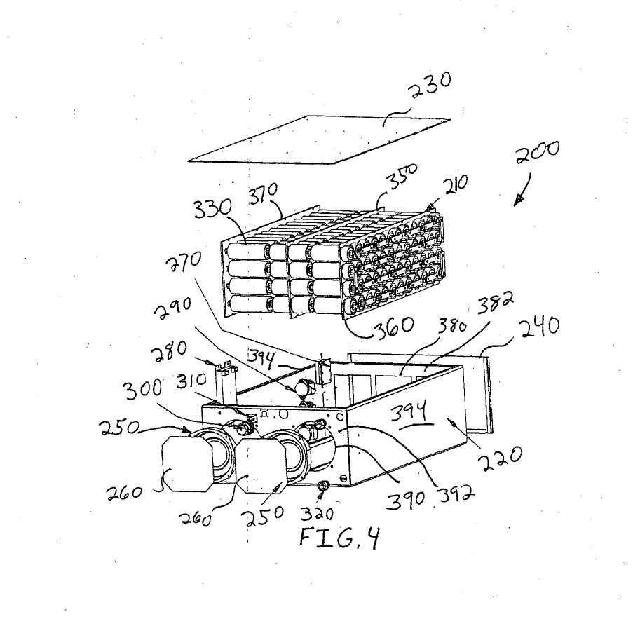

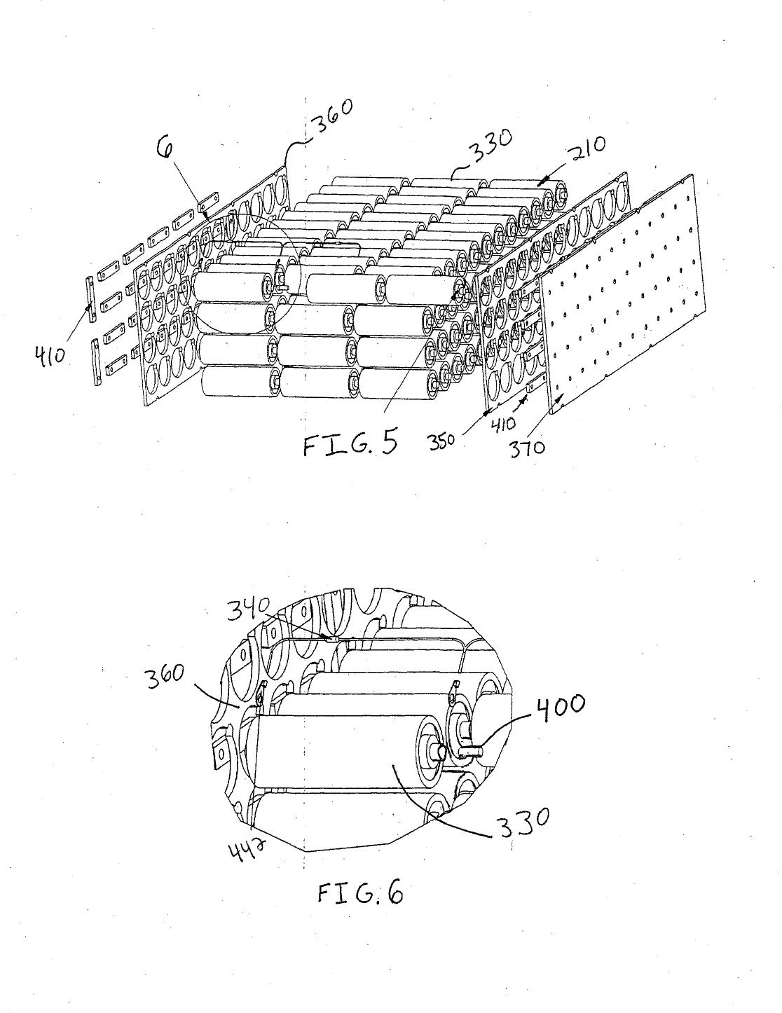

The ultracapacitor assembly 210 includes one-hundred and forty-four (144) ultracapacitors 330 connected in series to provide a nominal 360 volts DC, 325 watt-hours energy storage. The value of each ultracapacitor 330 is 2600 Farads. In alternative embodiments, the ultracapacitor assembly 210 may have other numbers of ultracapacitors, different types of ultracapacitors, and/or an overall different amount of voltage and/or power. Each ultracapacitor 330 is connected with a parallel balancing and drain discharge resistor 340 (FIG. 6). The ultracapacitor assembly 210 includes a first wine rack middle crate support plate 350, a similar second wine bottle rack type middle crate support plate 360, and a wine bottle rack type end crate support plate 370 for supporting the ultracapacitors 330.

The box enclosure 220 is preferably made of metal and includes square end cutouts 380 in rear wall 382 to accommodate air flow there through and circular cutouts 390 in front wall 392 to accommodate the cooling fans 250. The front wall 392 and rear wall 382 are joined by opposite parallel side walls 394. The filter(s) of the air filter bracket 240 is externally serviceable and fits over the square cutouts 380 of the rear wall 382. The interior of the box enclosure 220 and underside of the lid 230 is coated with a thick material that provides electrical insulation and corrosion protection as an additional level of safety for the box enclosure 220. The inner bottom of the box enclosure 220 includes support plate guides for mounting the wine rack middle support plates 350, 360 and end support plate 370.

FIG. 5 shows an exploded view of the ultracapacitor assembly 210. The ultracapacitors 330 are cylindrical canisters with aluminum female threaded connections at each end, which receive male threaded aluminum interconnection terminals 400 for connecting the ultracapacitors 330 in series. Aluminum bus bars 410 and aluminum interconnection washers are also used to interconnect the ultracapacitors 330 in series at the ends of the rows. Providing electrical connections made of aluminum metal prevents any corrosive galvanic effects from dissimilar metals. Optionally, the threaded connections are covered with a silicon dielectric grease to prohibit environmentally caused corrosion or with other liquid, paste, or gel grease to enhance the electrical and thermal conductivity, and/or protect against corrosion and loosening of the threaded connection.

The wine bottle rack type middle crate support plates 350, 360 and end crate support plate 370 are made of nonconductive plastic material to prevent any high-voltage arcing or other high-voltage leakage effects that could occur over time due to vibration and shock. The wine rack style middle crate support plates 350, 360 and end crate support plate 370 are different in construction to allow ease of assembly and replacement of any canister row.

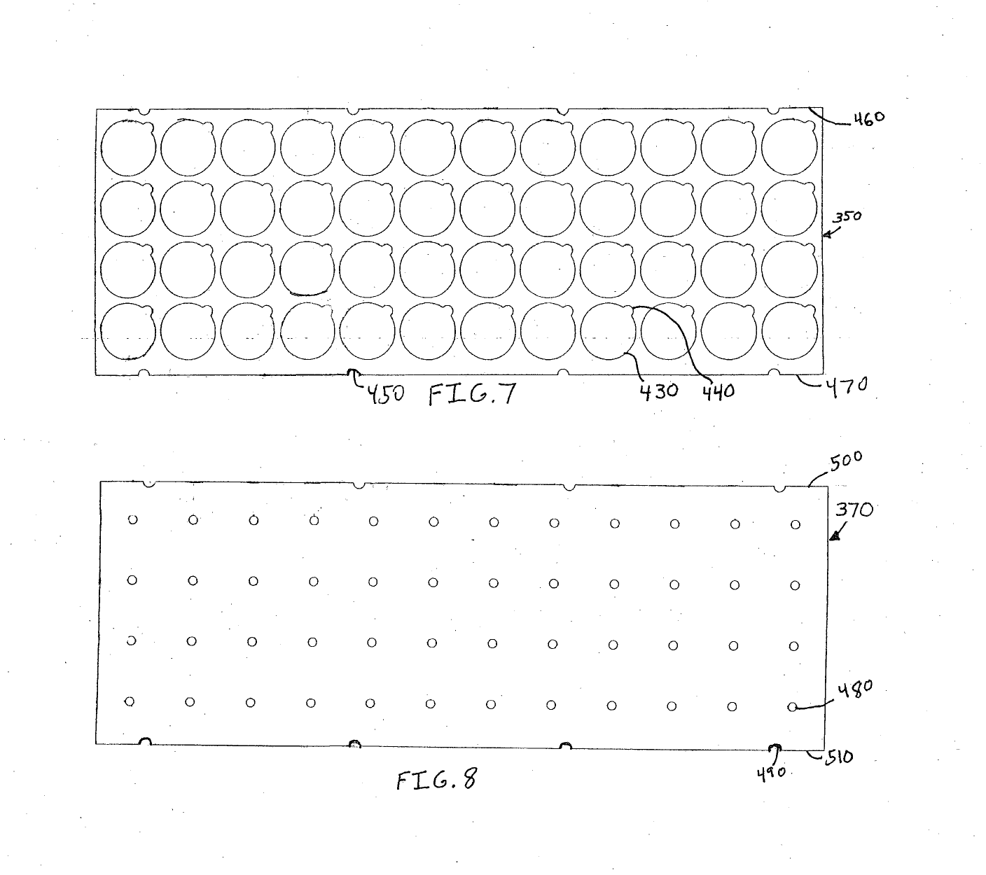

With reference to FIG. 7, the wine bottle rack type middle support plates 350, 360 include a pattern of generally circular cutouts 430 for receiving the ultracapacitors 330. The cutouts 430 include an additional semi-circular recess 440 to accommodate and support the body and leads of the individual drain resistors 340. The balancing and discharging drain resistors 340 are preformed with ring terminals 442 (FIG. 6) attached to leads of the drain resistors 340 for simplicity of mounting and electrical connection. Additional semi-circular recesses 450 along a top edge 460 and bottom edge 470 of the wine bottle rack type middle crate support plates 350, 360 provide clearance for the attaching rivets of support guides on a bottom of box enclosure 220 and the lid 230. The wine bottle rack type middle crate support plates 350, 360 are made of 3/16″ thick polycarbonate plastic for strength and electrical insulation.

With reference to FIG. 8, the wine bottle rack type end crate support plate 370 includes a pattern of circular holes 480 for receiving threaded bolt fasteners for mounting the ultracapacitors 330. Additional semi-circular recesses 490 along a top edge 500 and a bottom edge 510 of the wine bottle rack type end crate support plate 370 provide clearance for the attaching rivets of support guides on a bottom of the box enclosure 220 and the lid 230. The wine bottle rack type end crate support plate 370 is made of 3/16″ thick Grade G-10/FR4 Garolite glass fabric laminate with an epoxy resin that absorbs virtually no water and holds its shape well. Inside-mounted aluminum bus bars 410 are affixed in place to the wine rack end crate support plate 370 with silicon RTV (Room Temperature Vulcanizing, which is a common jelly-like paste that cures to a rubbery substance used in various applications as adhesive and/or sealer). The bus bars 410 are pre-positioned to avoid confusion that could cause assembly mistakes.

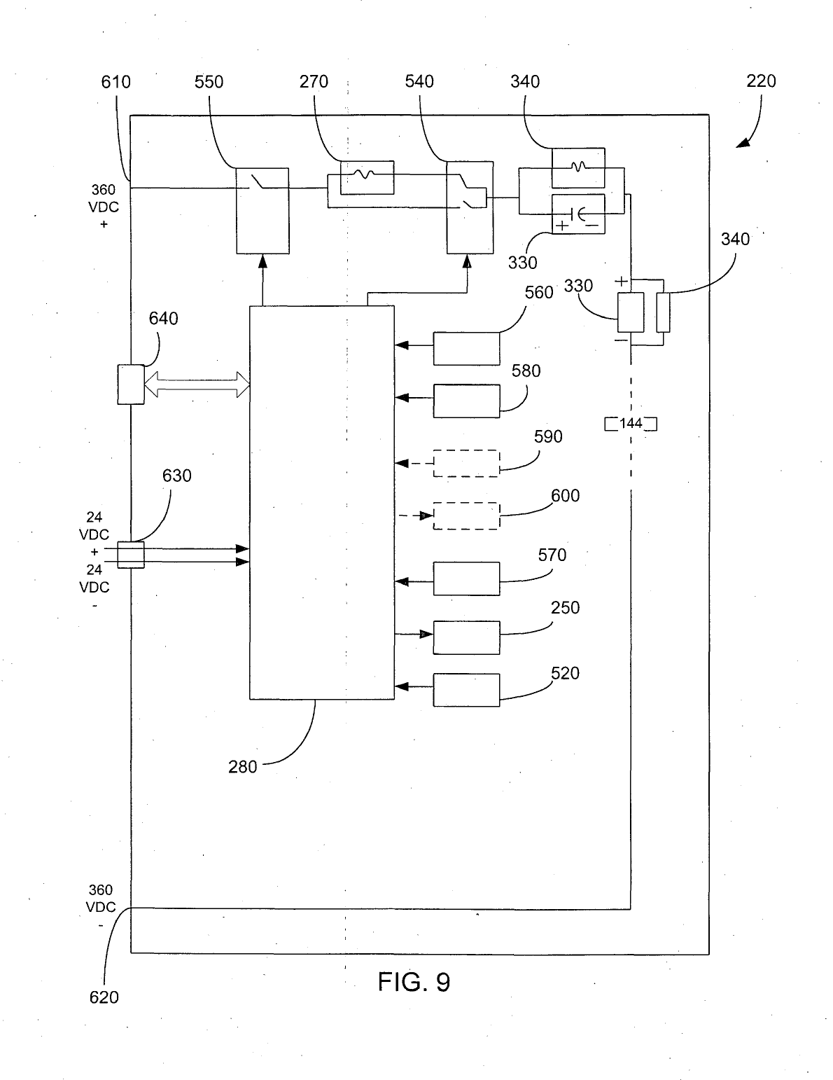

FIG. 9 is a general block diagram of the ultracapacitor pack 200. As indicated above, each ultracapacitor 330 is connected in parallel with the drain resistor 340. One-hundred and forty-four (144) of these parallel connections are connected in series to provide a nominal 360 volts DC, 325 watt-hours energy storage. The value of each ultracapacitor 330 is 2600 Farads and the value and power of the drain resistor 340 is selected to completely discharge the ultracapacitor 330 over a number of hours during an inactive period of the ultracapacitor pack 200. The balancing drain resistors form a resistor divider network to equalize each ultracapacitor and balance the pack assembly. The energy drain action is slow enough so as not to interfere with the normal operation of the ultracapacitor pack 200. The discharge is also slow enough so as not to cause any significant temperature increase from the drain resistors 340 within the ultracapacitor pack 200. The chemical composition of the ultracapacitor 330 allows charge to build up across the ultracapacitor 330 over a period of time after the ultracapacitor 330 is shorted and left open. The drain resistors 340 allow a safe discharge of the high voltage of the ultracapacitor pack 200 to eliminate any shock danger from the ultracapacitor “memory” to personnel servicing the ultracapacitor pack 200.

Because the ultracapacitors 330 can accept hundreds of amperes of electrical current during charging, a connection to an energy source would appear as a short circuit to the energy source. To accommodate this problem, a high-power pre-charge resistor 270 with its own heat sink is mounted inside the box enclosure 220 and used to limit the initial charging current. Based on input to a pack voltage sensor 520, the PLC 280 controls a pre-charge contactor relay 540 to engage the pre-charge resistor 270 until the ultracapacitors 330 reach a minimum safe voltage level.

The PLC 280 is the control center for additional features. Through a Control Area Network (CAN) bus interface (e.g., SAE standard J1939), the PLC 280 offers remote ON/OFF control and status reporting of: the control relay positions for on/off relay 550 and precharge relay 540, pack voltage sensor 520, ground fault interrupt (GFI) sensor 560, cooling fans 250, box temperature sensor(s) 570, over temperature sensor(s) 580, optional fire sensor 590, and optional fire suppression system 600. The PLC 280 also uses input from the box temperature sensor 570 to turn on and off the cooling fans 250. During normal operation of the ultracapacitor pack, the on/off relay 550 is activated. The on/off relay 550 is deactivated by the PLC 280 when the GFI sensor 560 detects a ground fault interrupt condition, when the over temperature sensor(s) 580 detects an over-temperature condition, or the pack voltage sensor 520 detects an over-voltage condition. The fire suppression system 600 is activated by the PLC 280 in the event a fire condition is detected by the fire sensor 590 to extinguish any fire in the ultracapacitor pack 200. A 360 VDC+ stud feed thru 610 is an external power cable attachment for the positive side of the ultracapacitor pack 200. A 360 VDC− stud feed thru 620 is an external power cable attachment for the negative side of the ultracapacitor pack 200. A 24 VDC+, 24 VDC− power connector 630 provides the positive and negative dc power connections for the PLC 280. A digital data interface connector 640 includes the wires that connect to the CAN bus network and is also the port by which the PLC 280 is programmed.

The ultracapacitor pack 200 includes structural support, environmental protection, automatic cooling, electrical interconnection of the ultracapacitors, remote ON/OFF switching, a safety pre-charge circuit, a safety and automatic equalizing discharge circuit, a programmable logic controller, a digital interface to a control area data network for control and status reporting, and an optional fire sensing and suppression system. The pack is ideal for high-voltage, high-power applications of electric and hybrid-electric vehicle propulsion systems, fixed site high-power load averaging, and high-power impulse requirements.

Additional embodiments of the ultracapacitor packs will be described.

In one or more embodiments of the ultracapacitor packs described herein, in addition to, or instead of cooling fan(s), the ultracapacitor pack includes a cooling system that is a forced-air refrigeration system or a liquid cooled cold plate attached to one or more external surfaces of the ultracapacitor pack enclosure.

In one or more embodiments of the ultracapacitor packs described herein, the controller (e.g., processor) for the ultracapacitor pack is either internal to or external to the ultracapacitor pack enclosure.

In one or more embodiments of the ultracapacitor packs described herein, the controller (e.g., processor) includes control algorithms and/or reporting algorithms. For example, but not by way of limitation, in one embodiment, the controller includes an algorithm to control one or more of the cooling system, precharge resistor control relay input, and on/off relay from one or more of the pack temperature sensor or sensors input, the voltage sensor input, the ground fault isolation input, the fire sensor input, and the fire suppression input. For example, but not by way of limitation, in another embodiment, the controller includes one or more algorithms for monitoring and reporting the sensor inputs to the control network interface, and/or includes one or more algorithms for controlling the cooling system and on/off relay in response to commands from the network interface.

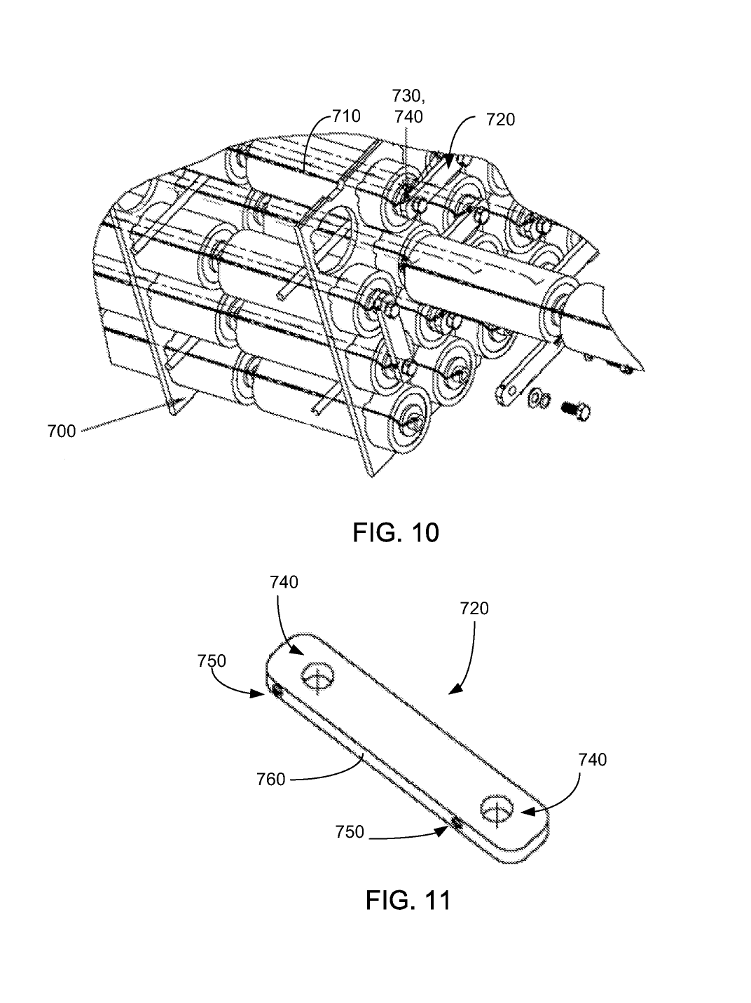

With reference to FIG. 10, a partial perspective view of another embodiment of an ultracapacitor energy storage cell pack 700 is shown. In this embodiment, passive balancing drain resistors 710 are attached directly to bus bar interconnects 720 via a small screw 730 and ring terminal 740. As shown in FIG. 11, the bus bar interconnect 720 includes a substantially flat, rectangular block configuration with vertical holes 740 near opposite ends to couple interconnection studs of adjacent ultracapacitors together in series. One or more laterally extending taps 750 extend into side 760 of the bus bar interconnect 720. The screw 730 and ring terminal 740 attach to the bus bar interconnect 720 at the taps 750 for attaching the passive balancing drain resistors 710 directly to the bus bar interconnects 720. Thus, in this embodiment, the ring terminal 740 at one end of the resistor 710 is fastened directly to the bus bar 720 with a screw 730 rather than placed around the threaded bolt between the capacitor can and the bus bar 720. Fastening the ring terminal 740 of the balancing resistor 710 to the bus bar 720 rather than across the connection bolt as was previously done removes that ring terminal 740 from the high current path through the ultracapacitors and results in a more consistently lower interconnect resistance between the ultracapacitor and the bus bar 720 for the high current path of the pack assembly 700.

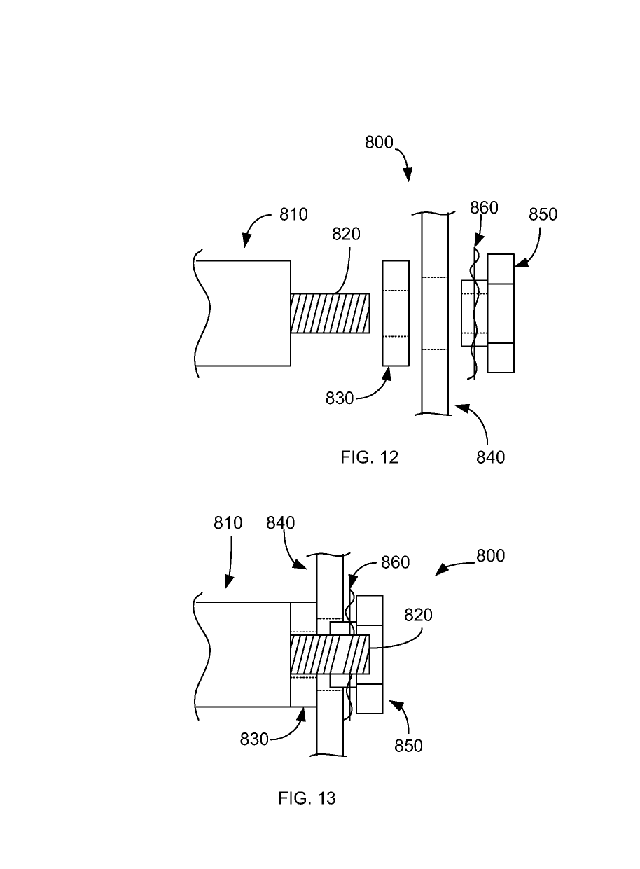

With reference to FIGS. 12 and 13, an embodiment of a fastening arrangement 800 at one side of an ultracapacitor energy storage cell pack is shown. In this embodiment of the ultracapacitor energy storage cell pack, ultracapacitor cans 810 include end terminals 820 that are male externally threaded studs rather than female internally threaded studs. In the fastening arrangement 800, a bus bar 830 is on the inside of an insulated wine rack support rack structure 840 with fastener 850 attaching to the externally threaded surface of the end terminal 820. The wine rack support structure 840 is somewhat similar to wine rack end support plate 370 shown and described above with respect to FIGS. 5 and 8. In the embodiment shown in FIGS. 12 and 13, the fastener 850 is a hexagonal internally threaded nut. A wave washer 860 is disposed between a flange of the fastener 850 and an outer side of the insulated support rack structure 840 to act as a lock washer and provide structure stability for wine rack support sheet 840. The fastening arrangement 800 ensures a solid electrical connection between the ultracapacitor 810 and the bus bar 830, and is important for keeping the connection resistance at a minimum between the ultracapacitor 810 and the bus bar 830.

The fastening arrangement 800 may be applied to the other ultracapacitor energy storage cell packs described herein. Thus, in alternative embodiments, the female internally threaded studs of the other ultracapacitor energy storage cell packs and fastening arrangements described herein are replaced with male externally threaded studs and the fastening arrangement 800.

With reference to FIGS. 14-20 an exemplary embodiment of an ultracapacitor cell-to-cell interconnection device (“interconnection device” or “interconnection”) and method for interconnecting connection studs of a string of ultracapacitor cans in series on substantially the same axis and in series and substantially alongside and parallel to each other (i.e., a bus bar type end plate).

The method of mechanically and electrically coupling the ultracapacitor cells in series, using cell-to-cell interconnection devices requires providing an interconnection that is electrically conductive, and of sufficient structural strength to support a first ultracapacitor and a second ultracapacitor when coupled to the interconnection. The interconnection is also configured to substantially prevent mechanical stress from forming in the coupled connection terminals of the first and the second ultracapacitor while maintaining the first ultracapacitor and the second ultracapacitor physically apart from each other without mechanically stressing the connecting terminals of the ultracapacitor cells. When incorporated into an energy storage cell pack, this will provide for a much more robust system which is safer against catastrophic failure. Thus, in a mobile application vibration and shock environment (e.g., in a transit bus), the ultracapacitor cans are less likely to crack and leak, protecting and preserving the ultracapacitor cells and the ultracapacitor pack.

With reference to FIG. 14, another way to look at the misalignment is to reference the axial direction along the cylinder 920 as defined by the outside surface of the cylinder and compare the deviation of the connecting stud's 910 cylindrical axis from being parallel to the cylindrical axis of the cell canister 920. In the past, when ultracapacitor cans 920 were connected together at the connection studs 910 mechanical stress could form in the coupled connection terminals when sufficient misalignment was present between the terminals 910 of the coupled ultracapacitors 920.

Referring to FIGS. 14-17 an exemplary embodiment of an ultracapacitor cell-to-cell interconnection device 900 and method for interconnecting connection studs of a string of ultracapacitor cans 920 of an ultracapacitor energy storage cell pack 930 will be described. Features of the ultracapacitor cans 920 and ultracapacitor energy storage cell pack 930 similar to those described above with respect to FIGS. 1-13 will not be described. Also, while it is contemplated that ultracapacitor cell-to-cell interconnection device 900 may take other forms, which retain the features of the above described method, ultracapacitor cell-to-cell interconnection device 900, as illustrated, represents an embodiment that is both inexpensive, and easy to manufacture and maintain.

In a preferred embodiment, the illustrated interconnection device 900 is a U-shaped bracket made of a material compatible with connection studs 910. Opposing flanges 960 extend perpendicularly from the rectangular span 940. The opposing flanges 960 each include a central hole 970 that receives the connection terminals 910 of the ultracapacitor cans 920. Fasteners 975, 980 in the form of a nut and a washer are used to connect each opposing flange 960 to connection studs 910.

As illustrated here connection studs 910 are made of aluminum metal. Thus, in order to match the metal composition of the storage cell stud and so as to prevent any galvanic corrosive effects of two dissimilar materials in electrical contact, interconnection 900 is preferably made of aluminum metal as well. Furthermore, according to one embodiment, interconnection 900 is formed from sheet with sufficient structural strength to align and support adjacent ultracapacitor cans 920, and sufficient ductility to substantially prevent mechanical stress from forming in ultracapacitor cans 920 upon installation.

Connecting the connection studs 910 in aligned, end-to-end ultracapacitor cans 920 together through the interconnection devices 900 removes the mechanical stress that might otherwise have been formed in a rigid, direct connection of the terminals 910. In particular, the flat plate and hole at each opposing flange 960, or leg of the “U”, allow the stud to go through the hole with some angular misalignment while simultaneously allowing the nut and washer to press/secure the flat plate 960 against the flat terminal surface of the canister without forcing the stud axis into parallel alignment with the canister cylinder axis. According to one embodiment, to improve fit and/or to isolate ultracapacitor can 920 poles, a spacer or bushing may also be interspersed between flange 960 and ultracapacitor can 920.

The preferred U-shaped interconnection brackets have their greatest inherent bending flexibility in the plane perpendicular to rectangular span 940 and though cylindrical axis of the cell canister 920. Thus to best accommodate the alignment manufacturing variations between the stud and the end surface of the cylindrical canister (terminal stud misalignments) the U-shaped bracket and the misaligned stud should be oriented to allow the U-shape flexing in the direction of the shaft misalignment. Preferably both canisters 920 will be oriented to take advantage of the interconnection's 900 flexing.

However, if the stud shaft misalignment is not oriented as such, the relatively thin material of the bracket will still allow some stud misalignment at any orientation of the bracket and stud as the stud passes through the hole in the bracket for example, due to: the size of the hole opening, the thickness of the bracket material, the ductility of the bracket metal, and the clamping action of the attaching nut and washer. Moreover, this does not affect the connection conductivity because the nut and washer forces the bracket material against the flat surface of the cell terminal on the end of the canister. Thus, potential stress caused in the connection terminals 910 by manufacturing tolerances that resulted in inconsistent stud alignment between the connecting studs and stud locations is eliminated or at least greatly reduced.

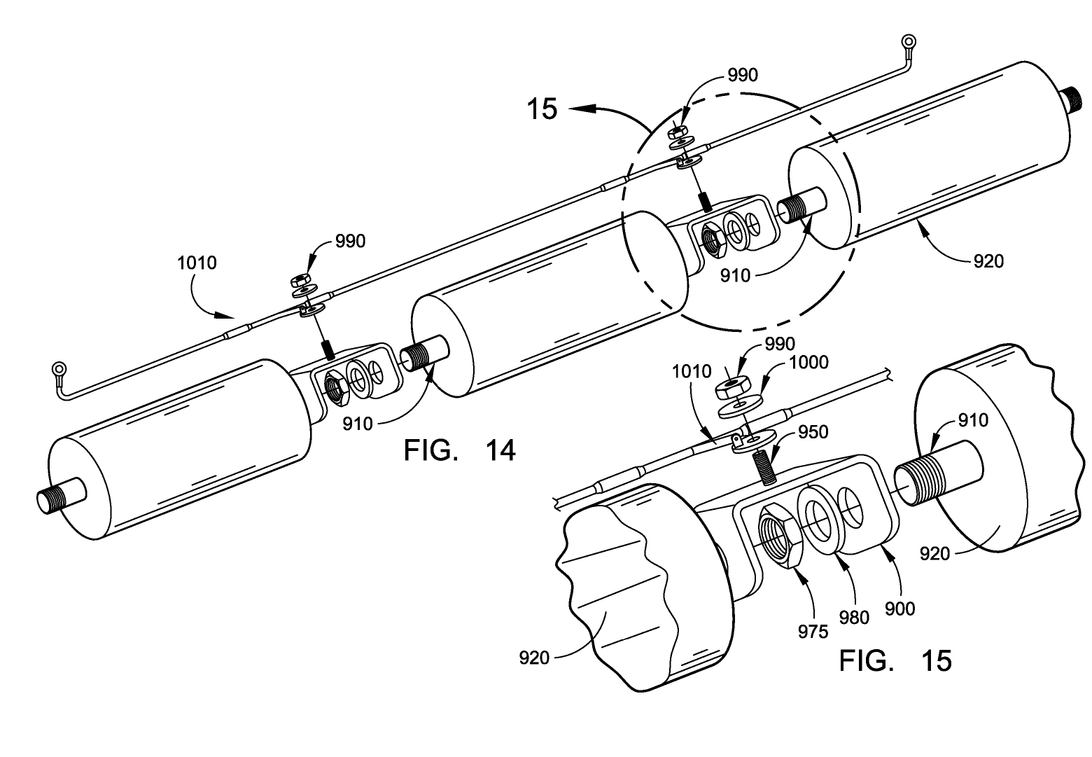

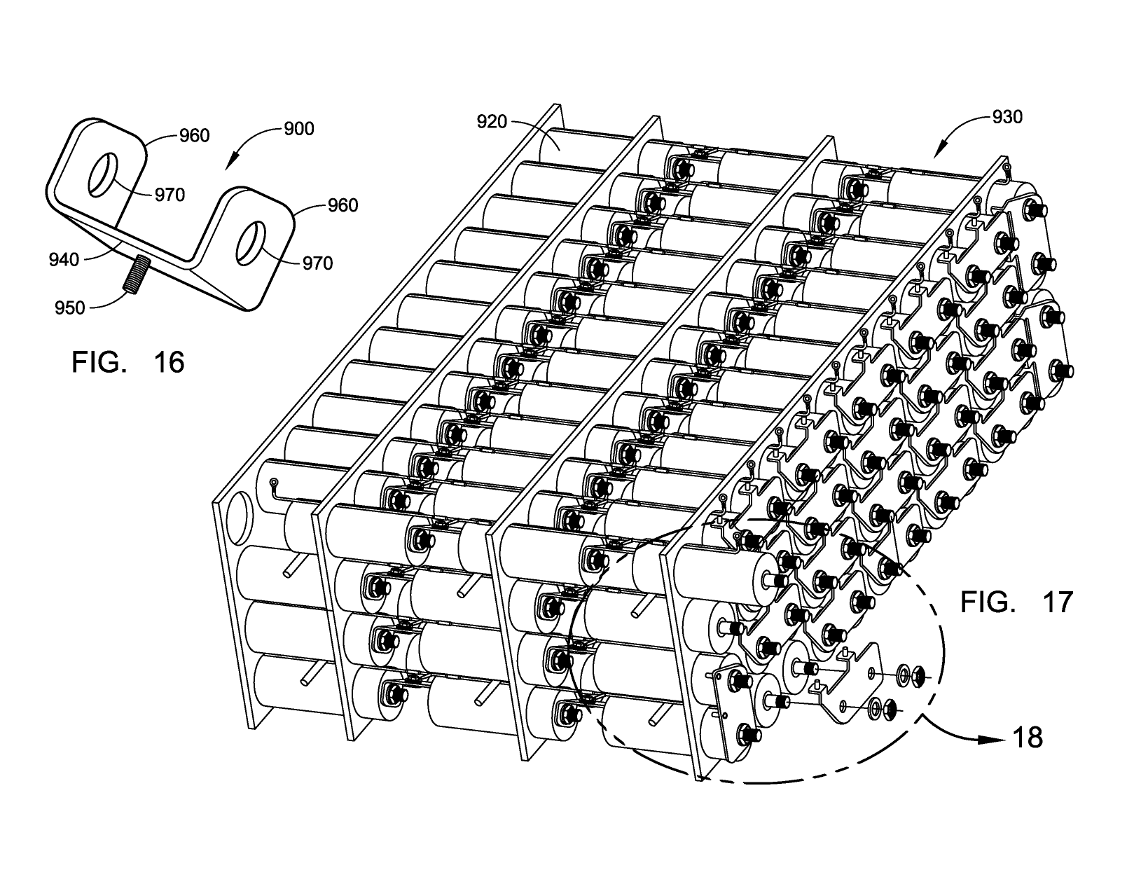

According to one embodiment, the illustrated interconnection device 900 includes an attachment interface for a balancing resistor node. In particular, interconnection device 900 may include an integrated threaded post configured to support a first balancing resistor and a second balancing resistor while forming an electrical node between the first balancing resistor and the second balancing resistor. For example, FIG. 16 shows interconnection device 900 having a rectangular span 940 with a hole centrally disposed therein for receiving an electrically-conductive, threaded captive stud 950, which forms an interface for a balancing resistor node. This configuration is preferable as it is inexpensive, it facilitates manufacture/assembly, and may incorporate standard parts.

Furthermore, upon assembly, the threaded captive stud 950 and fasteners 990, 1000 in the form of a nut and a washer are used to connect interconnection device 900 to ring terminals attached to leads of parallel balancing and discharging drain resistors 1010, which is similar to parallel balancing and discharging drain resistors 340 (FIG. 6) described above. The balancing and discharging drain resistors 1010 form a resistor divider network to equalize each ultracapacitor 920 and balance the pack assembly 930. The interconnection device 900, the threaded captive stud 950, and the fasteners 990, 1000 are all preferably made of aluminum.

In addition to supporting and electrically coupling a first ultracapacitor and a second ultracapacitor, interconnection 900 may also be configured thermally couple with a heat sink such as moving air and transfer heat from at least one of the first and the second ultracapacitor to the heat sink. For example, referring to FIG. 4 box enclosure 220 utilizes forced air flowing through the ultracapacitor energy storage cell pack. Here, interconnection 900 provides a thermal path from the end terminal of canister 920 to the cooling air stream, providing additional cooling to the ultracapacitor 920.

With reference to FIGS. 17-20, embodiments of bus bar interconnection end plates (“end plates”) 1100, 1200 of the ultracapacitor energy storage cell pack 930 will be described in turn. Similar to the exemplary cell-to-cell interconnection device 900 described above, end plates 1100, 1200 mechanically and electrically couple the ultracapacitor cells in series, and are of sufficient structural strength to support a first ultracapacitor and a second ultracapacitor when coupled to the interconnection. The interconnection is also configured to substantially prevent mechanical stress from forming in the coupled connection terminals of the first and the second ultracapacitor while maintaining the first ultracapacitor and the second ultracapacitor physically apart from each other without mechanically stressing the connecting terminals of the ultracapacitor cells. However, as an end plate, the coupled ultracapacitors will be substantially alongside and parallel to each other.

The bus bar interconnection end plates 1100, 1200 are not limited to any particular shape and composition, however, as end plate 1100 will typically be used in an ultracapacitor energy storage cell 930 pack having numerous ultracapacitors 920, end plates 1100, 1200 should provide sufficient clearance between neighboring coupled ultracapacitors 920, and be of a material compatible with connection studs 910.

Since most connection studs 910 are made of aluminum metal, end plate 1100 is preferably made of aluminum as well. Also, aluminum provides strength, ductility, electrical conductivity, and thermal conductivity. Providing electrical connections made of aluminum metal would thus prevent any corrosive galvanic effects from dissimilar metals. Optionally, the stud/hole connections shown and described herein are covered with a silicon dielectric grease to prohibit environmentally caused corrosion or with other liquid, paste, or gel grease to enhance the electrical and thermal conductivity, and/or protect against corrosion and loosening of the threaded connection.

According to one preferred embodiment, where the ultracapacitor cells are laid out in an array forming a single series circuit of all cells, and recognizing the need for electrical isolation from other coupled ultracapacitors, and the desirability of high performance and efficient manufacture, it is possible to use two patterns for the end plate interconnections. In particular, end plates 1100, 1200 also include a substantially flat, rectangular block configuration with a triangular-shaped corner 1110, 1210. As illustrated in FIG. 20, end plate 1100 includes holes 1120 near opposite ends to couple connection studs 910 of adjacent ultracapacitors 920 together in series. As illustrated in FIG. 19, end plate 1200 includes holes 1220 near opposite ends to couple interconnection studs 910 of adjacent ultracapacitors 920 together in series. The illustrated end plates 1100, 1200 are particularly well-suited for in expensive manufacture in an in-house machine shop, and provide for additional fixtures a large heat transfer surface.

As with interconnection device 900, end plates 1100, 1200 may also include the additional feature of an attachment interface for a balancing resistor node. In particular, end plates 1100, 1200 may include two integrated threaded posts configured to support a first balancing resistor and a second balancing resistor while forming an electrical node between the first balancing resistor and the second balancing resistor through the end plate.

As illustrated in FIG. 20, end plate 1100 also preferably includes holes that receive electrically conductive threaded captive studs 1140 in triangular-shaped corner 1110 and along edge 1130, between holes 1120. Likewise, as illustrated in FIG. 19, end plate 1200 also preferably includes holes that receive electrically conductive threaded captive studs 1240 in triangular-shaped corner 1210 and along edge 1230, between holes 1120. However, given the interior positioning of end plate 1200, relative to ultracapacitor energy storage cell pack 930, end plate 1200 will also include flange members 1235, which extend perpendicularly from the rest of end plate 1200 along edge 1230, between holes 1220 and from triangular-shaped corner 1210. The flange members 1235 include holes that receive electrically conductive threaded captive studs 1240. The end plate 1200 has a different configuration than end plate 1100 because of mechanical interference in the ultracapacitor pack 930. Also, in both configurations the connection studs could alternately be either partially threaded and partially press-in fit or full press-in fit.

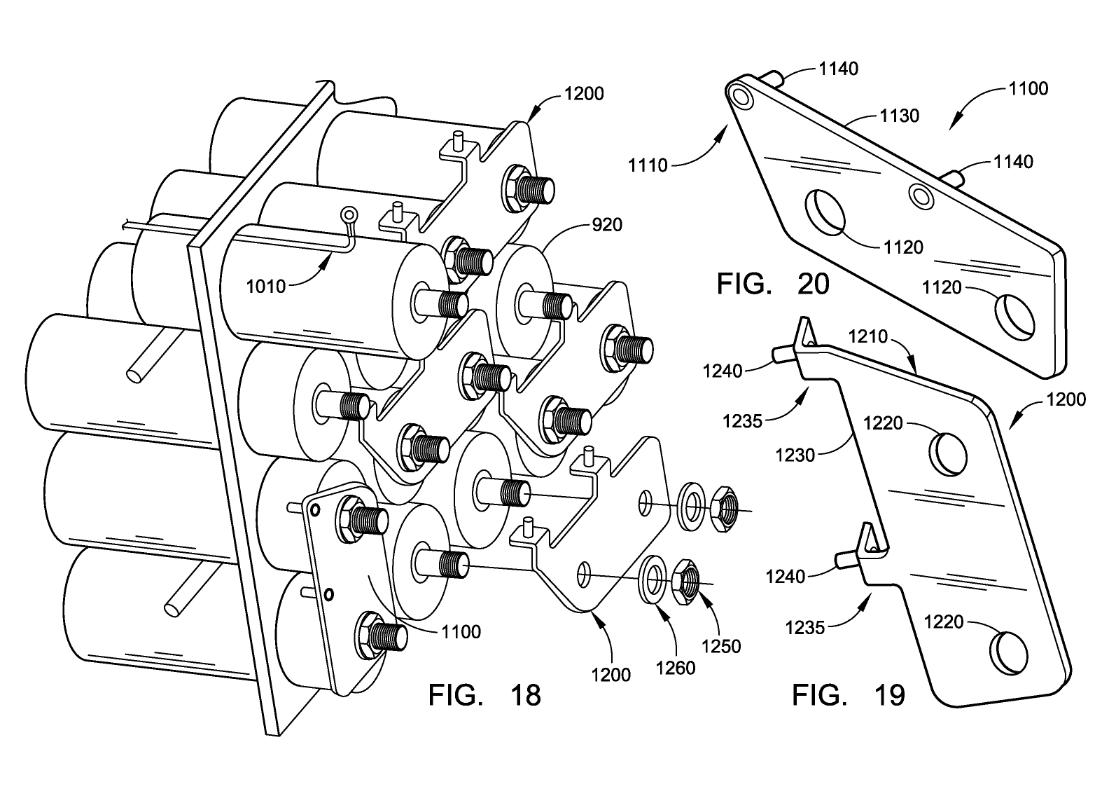

With reference to FIG. 18, adjacent capacitors 920 may be coupled together in series through end plates 1100, 1200 as shown. For example, capacitors may be coupled by connecting connection studs 910 of the capacitors 920 at the ends of the capacitor rows to end plates 1100, 1200 using fasteners 1250, 1260 in the form of nuts and washers. Similarly, threaded captive studs 1140, 1240 and fasteners (e.g., nuts 990, washers 1100) are used to directly connect end plates 1100, 1200 to the parallel balancing and discharging drain resistors 1010.

As with interconnection device 900, in addition to supporting and electrically coupling a first ultracapacitor and a second ultracapacitor, end plates 1100, 1200 may also be configured thermally couple with a heat sink such as moving air and transfer heat from at least one of the first and the second ultracapacitor to the heat sink. In addition to providing a low resistance electrical current conducting path, the end plates 1100, 1200 provide a good heat sink path for the transfer of heat from the cell canister stud terminals to the surrounding outside air.

One or more implementations of the aspect invention described above may include threaded electrical connections between each capacitor and the threaded connections may include a liquid, paste, or gel to enhance the electrical and thermal conductivity, and/or protect against corrosion and thread connection loosening

While embodiments and applications of this invention have been shown and described, it would be apparent to those in the field that many more modifications are possible without departing from the inventive concepts herein. The invention, therefore, is not to be restricted except in the spirit of the appended claims.

What is claimed is:

1. A method for supporting and electrically coupling a first ultracapacitor and a second ultracapacitor, each including opposite ends with connection terminals protruding therefrom, the method comprising:
providing an interconnection that is electrically conductive, and of sufficient structural strength to support the first ultracapacitor and the second ultracapacitor, wherein the interconnection is configured to substantially prevent mechanical stress from forming in the coupled connection terminals of the first and the second ultracapacitor while maintaining the first ultracapacitor and the second ultracapacitor physically apart from each other;
coupling the first ultracapacitor to the interconnection; and
coupling the second ultracapacitor to the interconnection.

2. The method of claim 1, wherein the interconnection is further configured to support a first balancing resistor and a second balancing resistor while forming an electrical node between the first balancing resistor and the second balancing resistor, the method further comprising:
coupling the first balancing resistor to the interconnection; and
coupling the second balancing resistor to the interconnection.

3. The method of claim 1, wherein the coupling the second ultracapacitor to the interconnection comprises: electrically coupling the first and the second ultracapacitor in series, and physically aligning the first and the second ultracapacitor on substantially the same axis.

4. The method of claim 1, wherein the interconnection comprises a bus bar type end plate; and
wherein the coupling the second ultracapacitor to the interconnection comprises:
electrically coupling the first and the second ultracapacitor in series, and physically aligning the first and the second ultracapacitor substantially alongside and parallel to each other.

5. The method of claim 1, wherein the interconnection is further configured to thermally couple with a heat sink such as moving air, the method further comprising:
coupling the interconnection with the heat sink; and
transferring heat from at least one of the first and the second ultracapacitor to the heat sink.

6. An ultracapacitor energy storage cell pack including a plurality of ultracapacitors, the ultracapacitor energy storage cell pack comprising:
a first ultracapacitor including opposite ends with connection terminals protruding therefrom;
a second ultracapacitor including opposite ends with connection terminals protruding therefrom, and configured to directly connect with the first ultracapacitor in series; and
a first interconnection configured to: electrically couple connection terminals of the first and the second ultracapacitor in series, mechanically support the first and the second ultracapacitor, and substantially prevent mechanical stress from forming in the coupled connection terminals of the first and the second ultracapacitor.

7. The ultracapacitor energy storage cell pack of claim 6, wherein the plurality of ultracapacitors includes a plurality of balanced ultracapacitors, the ultracapacitor energy storage cell pack further comprising a plurality of balancing resistors; and
wherein each of the plurality of balancing resistors is electrically coupled in parallel with at least one of the plurality of balanced ultracapacitors to form a resistor divider network that automatically discharges and equalizes the at least one of the plurality of balanced ultracapacitors over time, thereby automatically balancing the plurality of balanced ultracapacitors of the ultracapacitor energy storage cell pack.

8. The ultracapacitor energy storage cell pack of claim 6, wherein the first interconnection is further configured to electrically couple the first and the second ultracapacitor in series, and to physically align the first and the second ultracapacitor end-to-end on substantially the same axis.

9. The ultracapacitor energy storage cell pack of claim 8, wherein the first interconnection comprises a U-shaped bracket.

10. The ultracapacitor energy storage cell pack of claim 9, wherein the first interconnection is made from a material similar to the coupled connection terminals of the first and the second ultracapacitor, and includes a rectangular span having an attachment interface for a balancing resistor node and with opposing flanges extending approximately perpendicularly from the rectangular span, the opposing flanges including holes therein for receiving connection terminals of the first and the second ultracapacitor.

11. The ultracapacitor energy storage cell pack of claim 6, wherein the first interconnection is further configured to electrically couple the first and the second ultracapacitor in series, and to physically align the first and the second ultracapacitor substantially alongside and parallel to each other.

12. The ultracapacitor energy storage cell pack of claim 11, wherein the first interconnection comprises a bus bar type end plate.

13. The ultracapacitor energy storage cell pack of claim 12, wherein the first interconnection is made from a material similar to the coupled connection terminals of the first and the second ultracapacitor, and includes a set of holes therein for receiving connection terminals of the first and the second ultracapacitor, and an attachment interface for a balancing resistor node.

14. The ultracapacitor energy storage cell pack of claim 6, wherein the first interconnection is further configured to thermally couple with a heat sink.

15. The ultracapacitor energy storage cell pack of claim 14, wherein the heat sink comprises air moving across the first interconnection.
